(19) United States
(12) Patent Application Publication
(10) Pub. No.: US 2023/0343751 A1
(43) Pub. Date: Oct. 26, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yu-Cheng Yeh, Taichung City (TW); I-Hsin Lin, Taichung City (TW); Shao-Hua Chen, Taichung City (TW); Yi-Chen Chi, Taichung City (TW); Wen-We Su, Taichung City (TW); Kuo-Yi Chen, Taichung City (TW)

(73) Assignee: SILICONWARE PRECISION INDUSTRIES CO., LTD., Taichung City (TW)

(21) Appl. No.: 17/845,302

(22) Filed: Jun. 21, 2022

(30) Foreign Application Priority Data
Apr. 25, 2022 (TW) 111115641

(51) Int. Cl. H01L 25/065; H01L 23/00; H01L 23/31; H01L 21/56

(52) U.S. Cl. CPC H01L 25/0657; H01L 24/32; H01L 24/48; H01L 24/16; H01L 23/3128; H01L 21/56; H01L 2224/32145; H01L 2224/48225; H01L 2224/16225

(57) ABSTRACT

An electronic package is provided, in which a first electronic element and at least one support member are disposed on a carrier structure, a spacer is disposed on the first electronic element, and a second electronic element is disposed on the at least one support member and the spacer, so as to prevent the second electronic element from tilting during a wire bonding process.

### BACKGROUND

### 1. Technical Field

The present disclosure relates to a semiconductor packaging process, and more particularly, to an electronic package with multi-chip stacking structure and manufacturing method thereof.

### 2. Description of Related Art

With the evolution of semiconductor technique, semiconductor products have developed different types of packaging products. The early multi-chip packaging structure employed a side-by-side multi-chip packaging structure, wherein two or more chips are mounted side-by-side with each other on a main mounting surface of a common substrate. The connection between multi-chip and conductive circuits on the common substrate is generally achieved by wire bonding. However, the side-by-side multi-chip packaging structure has shortcomings of high packaging cost and large packaging dimension, such that the area of the common substrate increases with the increased number of chips.

In order to address the aforementioned problems of the prior art, a vertical stacking method is used to mount the added chips in recent years. The stacking method is in accordance to the design of the chips, and the respective wire bonding process is different.

As shown in FIG. 1, in a conventional semiconductor package 1, a first semiconductor chip 11 is mounted on a packaging substrate 10, a second semiconductor chip 12 is then stacked on the first semiconductor chip 11 via a spacer 13, and the first semiconductor chip 11 and the second semiconductor chip 12 are electrically connected to the packaging substrate 10 via a plurality of metal wires 110, 120 in a wire bonding manner.

Generally, a planar dimension of the second semiconductor chip 12 is greater than a planar dimension of the first semiconductor chip 11, thus the second semiconductor chip 12 needs to be offsetly placed relative to the position of the first semiconductor chip 11, such that the second semiconductor chip 12 protrudes from the first semiconductor chip 11, so as to facilitate the wire bonding process of the second semiconductor chip 12. That is, the wire bonding paths of the metal wires 120 on the second semiconductor chip 12 can avoid the arranged metal wires 110 on the first semiconductor chip 11.

However, tilting may occur (e.g., tilting direction N shown in FIG. 1) if the second semiconductor chip 12 protrudes too much from the first semiconductor chip 11, so that the subsequent processes (such as the wire bonding process of the second semiconductor chip 12) cannot be performed, and even the second semiconductor chip 12 may hit the packaging substrate 10 and be damaged.

Therefore, how to overcome the aforementioned drawbacks of the prior art has become an urgent issue to be addressed at present.

### SUMMARY

In view of the various shortcomings of the prior art, the present disclosure provides an electronic package, which comprises: a carrier structure having a first side and a second side opposing the first side; a first electronic element disposed on the first side of the carrier structure and electrically connected to the carrier structure; at least one support member disposed on the first side of the carrier structure; a spacer disposed on the first electronic element; and a second electronic element disposed on the at least one support member and the spacer and electrically connected to the carrier structure, wherein the second electronic element has a planar dimension greater than a planar dimension of the first electronic element.

The present disclosure further provides a manufacturing method for an electronic package, which comprises: providing a carrier structure having a first side and a second side opposing the first side; disposing a first electronic element and at least one support member on the first side of the carrier structure, wherein the first electronic element is electrically connected to the carrier structure; disposing a spacer on the first electronic element; and disposing a second electronic element on the at least one support member and the spacer, wherein the second electronic element is electrically connected to the carrier structure, and wherein the second electronic element has a planar dimension greater than a planar dimension of the first electronic element.

In the aforementioned electronic package and manufacturing method thereof, the first electronic element is electrically connected to the carrier structure via a plurality of first bonding wires.

In the aforementioned electronic package and manufacturing method thereof, the second electronic element is electrically connected to the carrier structure via a plurality of second bonding wires.

In the aforementioned electronic package and manufacturing method thereof, the spacer has a planar dimension less than the planar dimension of the first electronic element.

In the aforementioned electronic package and manufacturing method thereof, the at least one support member comprises a semiconductor material or a metal material.

In the aforementioned electronic package and manufacturing method thereof, the at least one support member is a dummy die.

In the aforementioned electronic package and manufacturing method thereof, a coefficient of thermal expansion of the at least one support member and a coefficient of thermal expansion of the first electronic element belong to a same level.

In the aforementioned electronic package and manufacturing method thereof, further comprising forming a packaging layer on the carrier structure, wherein the packaging layer encapsulates the first electronic element, the second electronic element, the spacer and the at least one support member.

In the aforementioned electronic package and manufacturing method thereof, further comprising forming a plurality of conductive elements on the second side of the carrier structure, wherein the plurality of conductive elements are electrically connected to the carrier structure.

As can be understood from the above, in the electronic package and manufacturing method thereof of the present disclosure, the second electronic element is supported by the support member and the spacer together. Therefore, compared with the prior art, the second electronic element will not tilt during the wire bonding process, so that the wire bonding process can be conducted smoothly, thereby preventing the second electronic element from colliding with the carrier structure and breaking.

### BRIEF DESCRIPTION OF THE DRAWINGS

FIG. 1 is a schematic side view of a conventional semiconductor package.

FIG. 2A-1, FIG. 2B-1, FIG. 2C-1 and FIG. 2D are schematic side views illustrating a method for manufacturing an electronic package according to the present disclosure.

FIG. 2A-2, FIG. 2B-2 and FIG. 2C-2 are schematic top views of FIG. 2A-1, FIG. 2B-1 and FIG. 2C-1, respectively.

FIG. 3A, FIG. 3B and FIG. 3C are schematic top views depicting other different aspects of FIG. 2A-2.

FIG. 4 is a schematic top view depicting another aspect of FIG. 2C-2.

### DETAILED DESCRIPTIONS

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

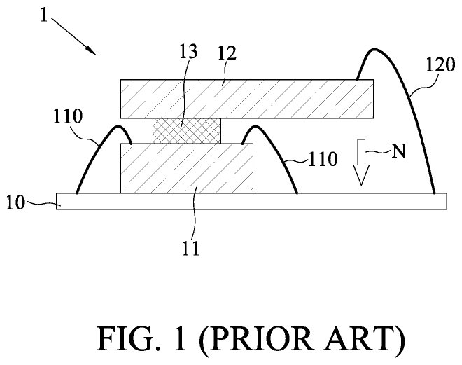

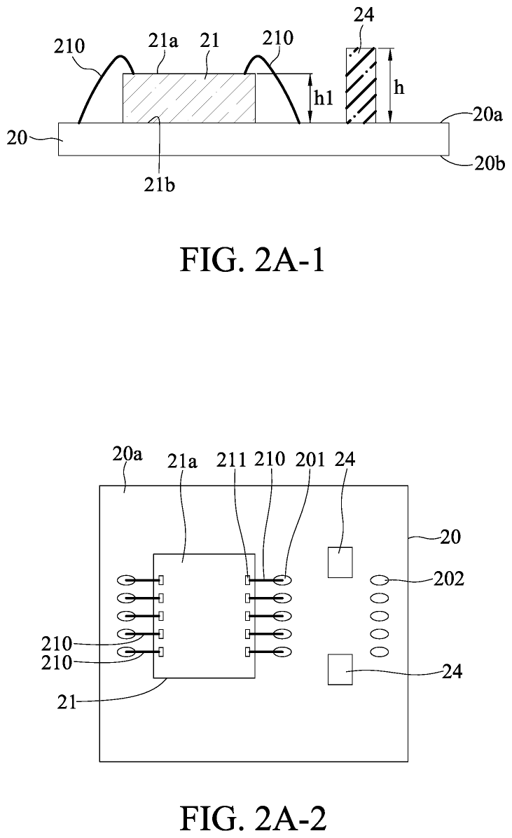

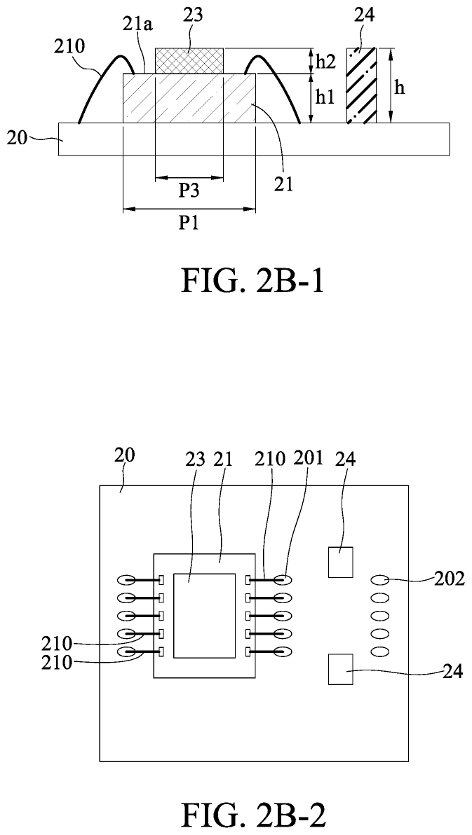

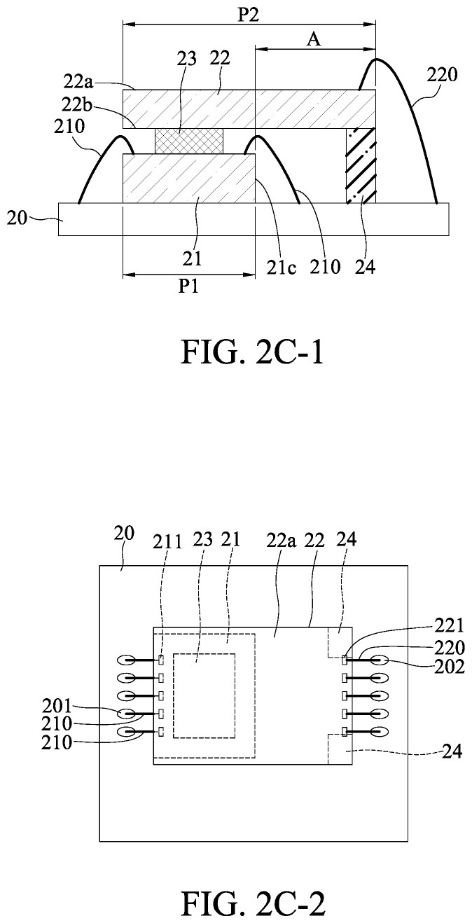

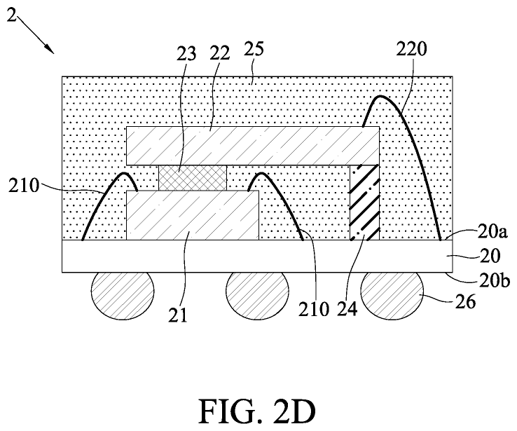

FIG. 2A-1, FIG. 2B-1 and FIG. 2C-1 are schematic cross-sectional views illustrating a method for manufacturing an electronic package 2 according to the present disclosure.

As shown in FIG. 2A-1, a carrier structure 20 is provided and has a first side 20a and a second side 20b opposite to the first side 20a, and at least one first electronic element 21 and at least one support member 24 are disposed on the first side 20a of the carrier structure 20 (FIG. 2A-2 shows two support members 24), so that the first electronic element 21 is electrically connected to the carrier structure 20.

In an embodiment, the carrier structure 20 can be a packaging substrate having a core layer and a circuit structure, or a coreless circuit structure, where a plurality of circuit layers such as redistribution layers (RDLs) are formed on a dielectric material, and the outermost layer of the circuit layers has a plurality of electrical contact pads 201, 202. However, in other embodiments, the carrier structure 20 can be a semiconductor substrate having a plurality of through-silicon vias (TSVs) so as to serve as a through-silicon interposer (TSI). As a result, the carrier structure 20 can be any carrier unit, such as a lead frame, for carrying electronic elements such as chips and the like, but the present disclosure is not limited to the above.

Further, the first electronic element 21 is an active element, a passive element, or a combination of the active element and the passive element, where the active element is such as a semiconductor chip, and the passive element is such as a resistor, a capacitor, or an inductor. In an embodiment, the first electronic element 21 is a rectangular semiconductor chip and has an active surface 21a and an inactive surface 21b opposite to the active surface 21a, where the first electronic element 21 is adhesively fixed on the carrier structure 20 via a bonding layer (not shown) by the inactive surface 21b thereof, and the active surface 21a has a plurality of electrode pads 211, as shown in FIG. 2A-2, so that a plurality of first bonding wires 210 are electrically connected to the electrode pads 211 and the electrical contact pads 201 by a wire bonding method.

Furthermore, the support member 24 is a bulk of a semiconductor material (such as silicon) and has a column shape or a wall shape. The support member 24 is free from being electrically connected to the carrier structure 20 and the first electronic element 21, and is spaced apart from the first electronic element 21. For instance, the support member 24 is a dummy die or a glass sheet. Alternatively, the support member 24 can be a metal bulk, where a coefficient of thermal expansion (CTE) of the support member 24 is close to a coefficient of thermal expansion of the first electronic element 21, such that the coefficient of thermal expansion of the support member 24 and the coefficient of thermal expansion of the first electronic element 21 belong to the same level.

In addition, a height h of the support member 24 is greater than a height h1 of the first electronic element 21.

As shown in FIG. 2B-1, at least one spacer 23 is disposed on the active surface 21a of the first electronic element 21.

In an embodiment, the spacer 23 can be a buffer die, a shield, a heat sink, or an insulator, even a functional chip, and the height h of the support member 24 is equal to the sum of the height h1 of the first electronic element 21 and a height h2 of the spacer 23.

Moreover, the spacer 23 is a rectangle as shown in FIG. 2B-2, a planar dimension P3 (or a base area) thereof is less than a planar dimension P1 (or an area of the active surface 21a) of the first electronic element 21, so as to prevent the spacer 23 from interfering with the arranged position of the first bonding wires 210. Alternatively, the spacer 23 can also be a bonding film and formed on the whole active surface 21a by a Film over Wire (FOW) method so as to encapsulate local line segments of the first bonding wires 210.

It should be understood that there are many kinds of the spacer 23, as long as elements can be stacked thereon, and the present disclosure is not limited to as such.

As shown in FIG. 2C-1, at least one second electronic element 22 is disposed on the spacer 23 and the support member 24, so that the second electronic element 22 completely covers the first electronic element 21, and the support member 24 is free from being electrically connected to the second electronic element 22.

In an embodiment, the second electronic element 22 is an active element, a passive element, or a combination of the active element and the passive element, where the active element is such as a semiconductor chip, and the passive element is such as a resistor, a capacitor, or an inductor. For instance, the second electronic element 22 is a semiconductor chip and has an active surface 22a and an inactive surface 22b opposite to the active surface 22a, where the second electronic element 22 is disposed on the spacer 23 and the support member 24 by the inactive surface 22b thereof, and the active surface 22a has a plurality of electrode pads 221, as shown in FIG. 2C-2, so that a plurality of second bonding wires 220 are electrically connected to the electrode pads 211 and the electrical contact pads 202 by a wire bonding method.

Further, a planar dimension P2 of the second electronic element 22 is greater than the planar dimension P1 of the first electronic element 21, so that the second electronic element 22 protrudes from a side surface 21c of the first electronic element 21, such that the inactive surface 22b of a protrusion portion A of the second electronic element 22 covers and abuts against the support member 24. For instance, the second electronic element 22 is a rectangle, such that the support member 24 is located at the edge of the inactive surface 22b of the protrusion portion A of the second electronic element 22, such as the corner shown in FIG. 2C-2.

Furthermore, the position of the second electronic element 22 relative to the position of the first electronic element 21 is offset toward one direction (as shown in FIG. 2C-1) rather than centered, so that the second electronic element 22 protrudes from the side surface 21c of the first electronic element 21, so as to facilitate the wire bonding process of the second electronic element 22. That is, the wire bonding paths of the second bonding wires 220 can avoid the arranged first bonding wires 210.

In addition, when the second electronic element 22 is placed, the second electronic element 22 will not interfere with the arrangement of the first bonding wires 210 on the first electronic element 21 due to the design of the spacer 23.

As shown in FIG. 2D, a packaging layer 25 is formed on the first side 20a of the carrier structure 20 to encapsulate the first electronic element 21, the second electronic element 22, the spacer 23, the support members 24, the first bonding wires 210 and the second bonding wires 220, and a plurality of conductive elements 26 such as solder balls are formed on the second side 20b of the carrier structure 20, such that the conductive elements 26 are electrically connected to the carrier structure 20.

In an embodiment, the packaging layer 25 is an insulating material, such as polyimide (PI), dry film, encapsulant such as epoxy resin, or molding compound, which can be formed on the carrier structure 20 by means of lamination or molding.

Hence, in the manufacturing method of the present disclosure, the support member 24 is arranged to support the protrusion portion A of the second electronic element 22. Therefore, compared with the prior art, the second electronic element 22 will not tilt during the wire bonding process, so that the second bonding wires 220 can be fabricated smoothly, thereby preventing the second electronic element 22 from colliding with the carrier structure 20 and breaking.

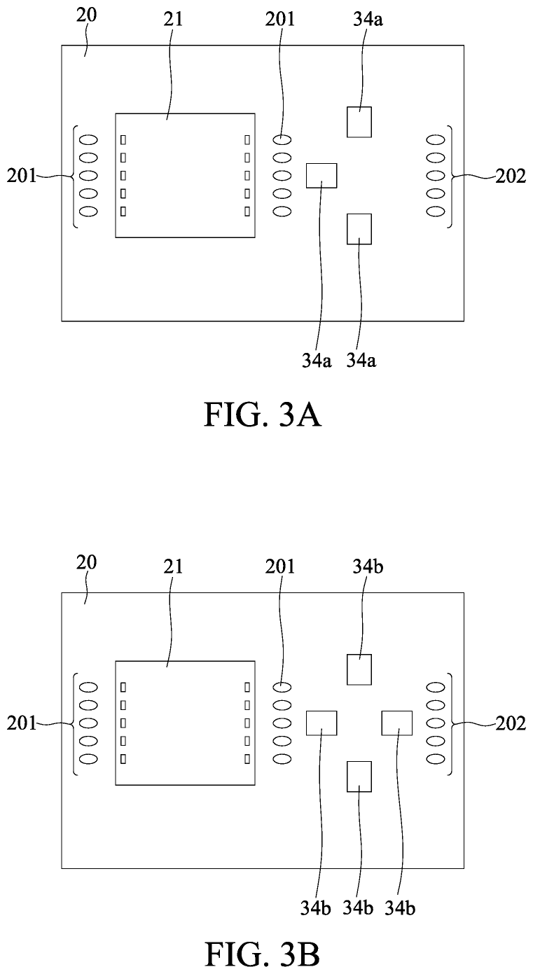

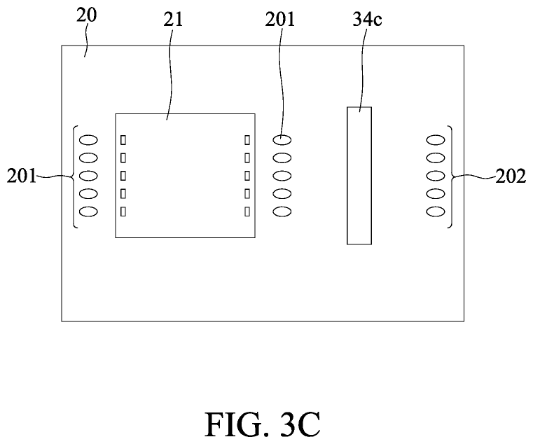

It should be understood that the support member 24 is used to prevent the second electronic element 22 from tilting, thus the amount, shape and position of the support member 24 can be configured according to the requirements. For instance, FIG. 3A shows three support members 34a, FIG. 3B shows four support members 34b, and FIG. 3C shows one wall-shaped support member 34c. The support members 24, 34a, 34b, 34c are adjusted based on the arrangement of firmly supporting the second electronic element 22 (or the protrusion portion A), and the present disclosure is not limited to as such.

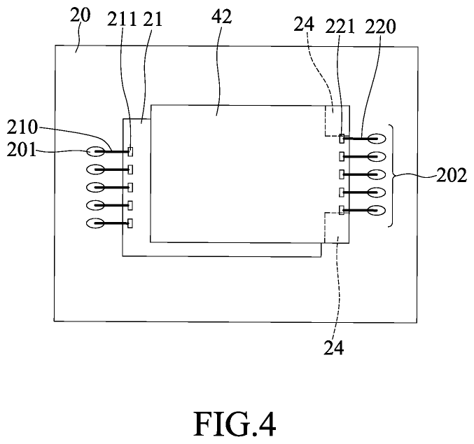

In addition, a second electronic element 42 can be free from completely covering the first electronic element 21, as shown by the dislocation state in FIG. 4. However, the second electronic element 42 can be effectively supported by the arrangement of the support member 24 so as to prevent the second electronic element 42 from tilting during the wire bonding process.

The present disclosure also provides an electronic package 2, which comprises: a carrier structure 20, a first electronic element 21, at least one support member 24, 34a, 34b, 34c, a spacer 23, and a second electronic element 22, 42.

The carrier structure 20 has a first side 20a and a second side 20b opposing to the first side 20a.

The first electronic element 21 is disposed on the first side 20a of the carrier structure 20 and electrically connected to the carrier structure 20.

The support member 24, 34a, 34b, 34c is disposed on the first side 20a of the carrier structure 20.

The spacer 23 is disposed on the first electronic element 21.

The second electronic element 22, 42 is disposed on the spacer 23 and the support member 24, 34a, 34b, 34c and is electrically connected to the carrier structure 20, wherein the second electronic element 22, 42 has a planar dimension P2 greater than a planar dimension P1 of the first electronic element 21.

In one embodiment, the first electronic element 21 is electrically connected to the carrier structure 20 via a plurality of first bonding wires 210.

In one embodiment, the second electronic element 22 is electrically connected to the carrier structure 20 via a plurality of second bonding wires 220.

In one embodiment, the spacer 23 has a planar dimension P3 less than the planar dimension P1 of the first electronic element 21.

In one embodiment, the support member 24, 34a, 34b, 34c comprises a semiconductor material or a metal material.

In one embodiment, the support member 24, 34a, 34b, 34c is a dummy die.

In one embodiment, a coefficient of thermal expansion of the support member 24, 34a, 34b, 34c and a coefficient of thermal expansion of the first electronic element 21 belong to a same level.

In one embodiment, the electronic package 2 further comprises a packaging layer 25 formed on the carrier structure 20, wherein the packaging layer 25 encapsulates the first electronic element 21, the second electronic element 22, 42, the spacer 23, and the support member 24, 34a, 34b, 34c.

In one embodiment, the electronic package 2 further comprises a plurality of conductive elements 26 formed on the second side 20b of the carrier structure 20 and electrically connected to the carrier structure 20.

To sum up, in the electronic package and the manufacturing method thereof according to the present disclosure, the second electronic element is supported by the support member, so that the second electronic element will not tilt during the wire bonding process. Therefore, the present disclosure can not only smoothly carry out the wire bonding process, but also prevent the second electronic element from colliding with the carrier structure and breaking.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure having a first side and a second side opposing the first side;
a first electronic element disposed on the first side of the carrier structure and electrically connected to the carrier structure;
at least one support member disposed on the first side of the carrier structure;
a spacer disposed on the first electronic element; and
a second electronic element disposed on the at least one support member and the spacer and electrically connected to the carrier structure, wherein the second electronic element has a planar dimension greater than a planar dimension of the first electronic element.

2. The electronic package of claim 1, wherein the first electronic element is electrically connected to the carrier structure via a plurality of first bonding wires.

3. The electronic package of claim 1, wherein the second electronic element is electrically connected to the carrier structure via a plurality of second bonding wires.

4. The electronic package of claim 1, wherein the spacer has a planar dimension less than the planar dimension of the first electronic element.

5. The electronic package of claim 1, wherein the at least one support member comprises a semiconductor material or a metal material.

6. The electronic package of claim 1, wherein the at least one support member is a dummy die.

7. The electronic package of claim 1, wherein a coefficient of thermal expansion of the at least one support member and a coefficient of thermal expansion of the first electronic element belong to a same level.

8. The electronic package of claim 1, further comprising a packaging layer formed on the carrier structure and encapsulating the first electronic element, the second electronic element, the spacer and the at least one support member.

9. The electronic package of claim 1, further comprising a plurality of conductive elements formed on the second side of the carrier structure and electrically connected to the carrier structure.

10. A method for manufacturing an electronic package, comprising:
providing a carrier structure having a first side and a second side opposing the first side;
disposing a first electronic element and at least one support member on the first side of the carrier structure, wherein the first electronic element is electrically connected to the carrier structure;
disposing a spacer on the first electronic element; and
disposing a second electronic element on the at least one support member and the spacer, wherein the second electronic element is electrically connected to the carrier structure, and wherein the second electronic element has a planar dimension greater than a planar dimension of the first electronic element.

11. The method of claim 10, wherein the first electronic element is electrically connected to the carrier structure via a plurality of first bonding wires.

12. The method of claim 10, wherein the second electronic element is electrically connected to the carrier structure via a plurality of second bonding wires.

13. The method of claim 10, wherein the spacer has a planar dimension less than the planar dimension of the first electronic element.

14. The method of claim 10, wherein the at least one support member comprises a semiconductor material or a metal material.

15. The method of claim 10, wherein the at least one support member is a dummy die.

16. The method of claim 10, wherein a coefficient of thermal expansion of the at least one support member and a coefficient of thermal expansion of the first electronic element belong to a same level.

17. The method of claim 10, further comprising forming a packaging layer on the carrier structure, wherein the packaging layer encapsulates the first electronic element, the second electronic element, the spacer and the at least one support member.

18. The method of claim 10, further comprising forming a plurality of conductive elements on the second side of the carrier structure, wherein the plurality of conductive elements are electrically connected to the carrier structure.
